(19) United States
(12) Patent Application Publication
(10) Pub. No.: US 2010/0307058 A1
(43) Pub. Date: Dec. 9, 2010

(54) Light barrier housing, light barrier element and door devices

(75) Inventors: Michael Sanke, Rheda-Wiedenbruck (DE); Franz Ziesché, Halle/Westfalen (DE); Patrick Euteneuer, Melle (DE)

Correspondence Address: GLOBAL IP COUNSELORS, LLP, 1233 20TH STREET, NW, SUITE 700, WASHINGTON, DC, 20036-2680, US

(73) Assignee: HORMANN KG ANTRIEBSTECHNIK, STEINHAGEN (DE)

(21) Appl. No.: 12/095,694

(22) PCT Filed: Nov. 22, 2006
(86) PCT No.: PCT/DE06/02061

§ 371 Date: Jul. 26, 2010

(30) Foreign Application Priority Data
Nov. 30, 2005 (DE) 20-2005-018-921.9
Mar. 2, 2006 (DE) 20-2006-003-313.0

(51) Int. Cl. H01L 31/16; H01L 31/0203; E05F 15/20

(52) U.S. Cl. 49/31; 250/239; 250/215

(57) ABSTRACT

A light barrier housing is provided in a light barrier for monitoring an automatically driven architectural closure. In order to reduce mounting work, a cable connection having at least one clamped connection is provided.

The invention relates to a light barrier housing having the features as it reads from the preamble of the attached claim 1 as is known from German patent DE 20 2004 005 113 U1. The invention relates furthermore to a light barrier element with one such light barrier housing and to a light barrier comprising one such element for a building closure, particularly a door. The invention relates in addition to a building closure, particularly a door, provided with one such light barrier, as well as to a door operator assigned to such a light barrier, where necessary including the controller. The invention is thus especially involved in the art of monitoring automated building closures, especially automated doors.

The aformentioned German patent DE 20 2004 005 113 U1 describes a light barrier for monitoring an automated door by two light barrier elements, both in two-wire technology for installing a light barrier link in or at a doorway. This system thus requires only two connecting wires per light barrier element sufficient for both signal and power transmission, making for a significant simplification in assembly as compared to prior art light barrier devices for building closures involving at least three connecting wires.

It is on the basis of this prior art that the object of the invention is to further simplify fitting the light barrier element.

This object is achieved by the subject matter of the independent claims.

Advantageous aspects of the invention form the subject matter of the sub-claims.

In accordance with the invention for making the cable connection of a light barrier element clip-on terminals are used as known hitherto only for loudspeaker connections in audio systems. This thus now makes it possible for the connections to be made by a non-professional in installing the light barrier in accordance with the invention absolutely foolproof and straight-forward.

To advantage self-adhesive or clip-on cable clips can be employed for routing the cable, here again for very simple and effective handling.

This now achieves major simplifications in installing light barriers as compared to prior art, there now being no need for a professional electrician to do the job. Anyone who can set up and connect his audio system at home can now install the light barrier housing in accordance with the invention just as easily. Since the cost of installing existing light barriers was a deciding factor, the invention now eliminates this factor in making a major contribution towards dissemination of such light barriers vital to safe operation of automated doors. This also now makes it possible to offer light barrier systems also for door operators of the lower cost category as are currently very popular, for example, on garage doors of single household dwellings without substantially adding to the costs involved.

It is understood that the term “light barrier” is not restricted to the use of visible light, but is intended to include all and any form of beaming, particularly infrared, for detecting objects in the path between two light barrier elements—transmitter and receiver or transceiver and reflector.

In accordance with one advantageous aspect the housing of the individual light barrier elements is provided with a detent means by means of which the housing can now be simply clipped to edgings or holes/notches in a door member or mounting fixture.

Example aspects of the invention will now be detailled with reference to the attached drawings in which:

FIG. 1 is a front view of a light barrier housing of a light barrier element;

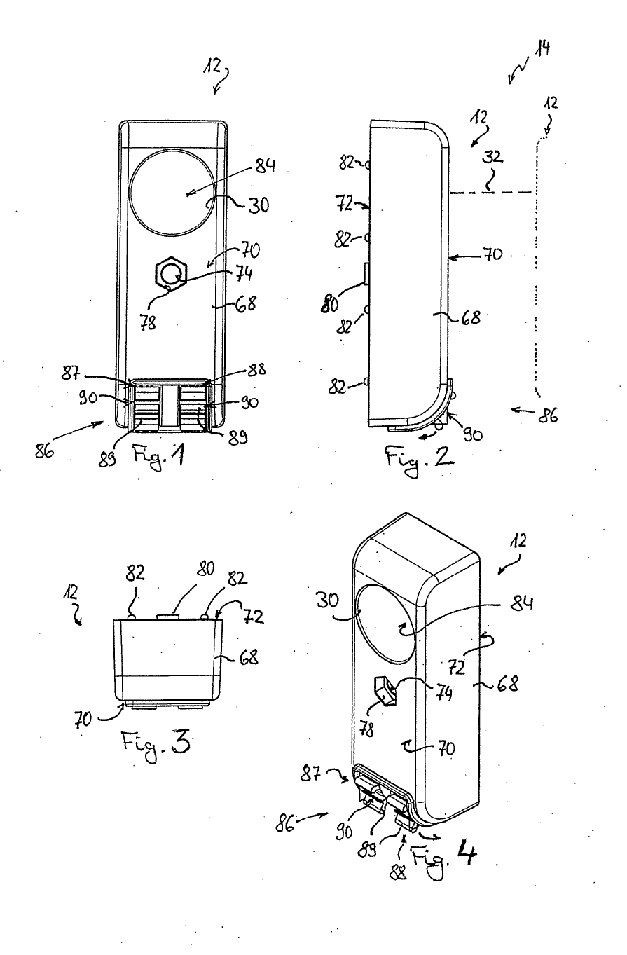

FIG. 2 is a side view of the light barrier housing;

FIG. 3 is a top-down view of the light barrier housing;

FIG. 4 is a view in perspective of the light barrier housing as seen from the front, top-down and from the side;

FIG. 5 is a view in perspective of the light barrier housing secured to a mounting fixture in the form of a mounting bracket in a first mounting position, this first mounting position being suitable for mounting on the floor;

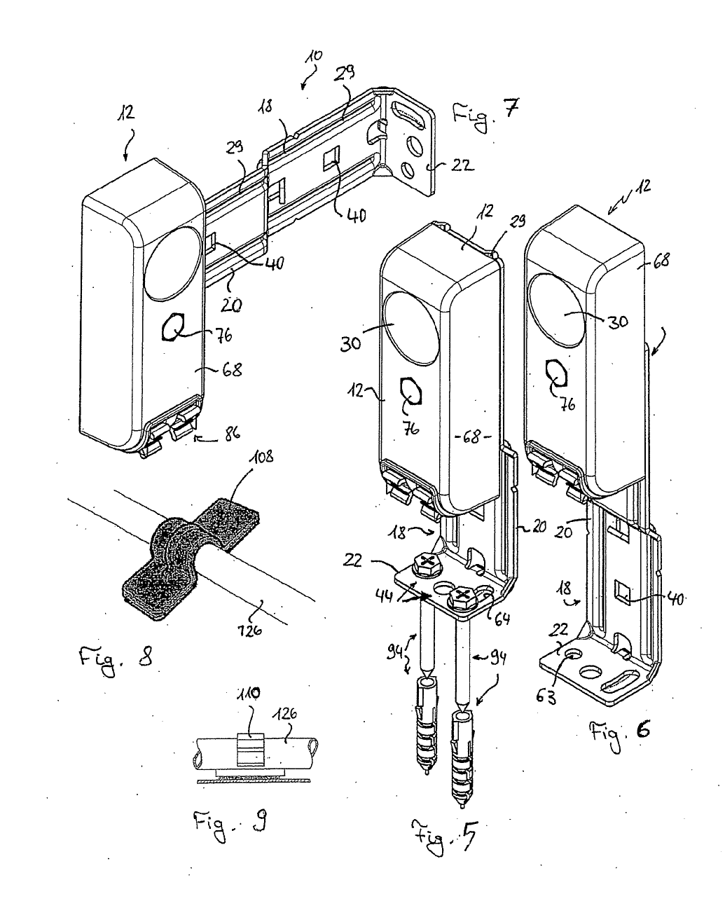

FIG. 6 is a view in perspective of a second mounting position of a light barrier housing and mounting bracket suitable for floor mounting;

FIG. 7 is a view in perspective of a third mounting position of a light barrier housing and mounting fixture suitable for securing to a door frame of a single leaf overhead door;

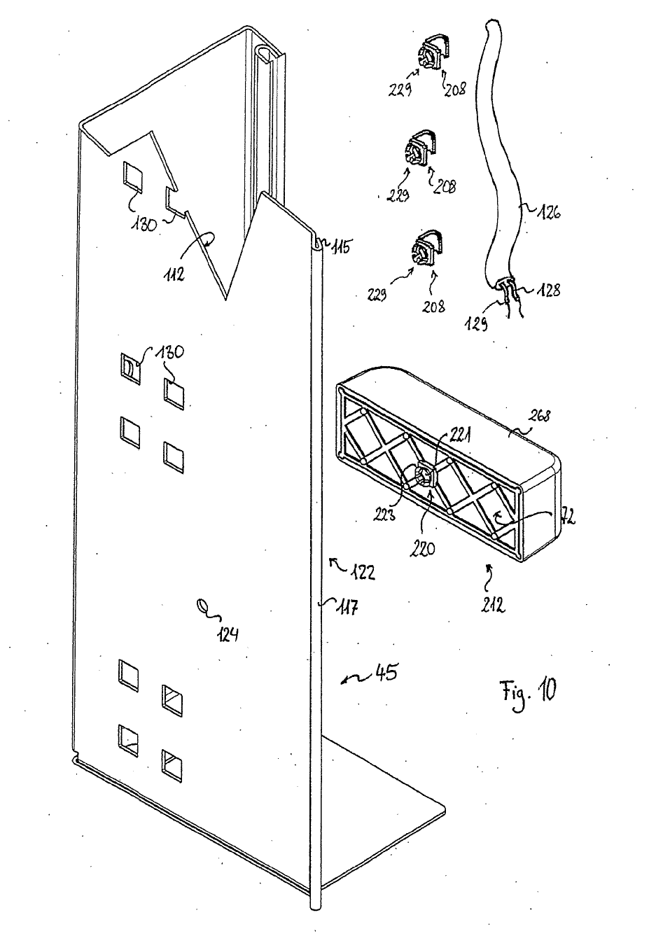

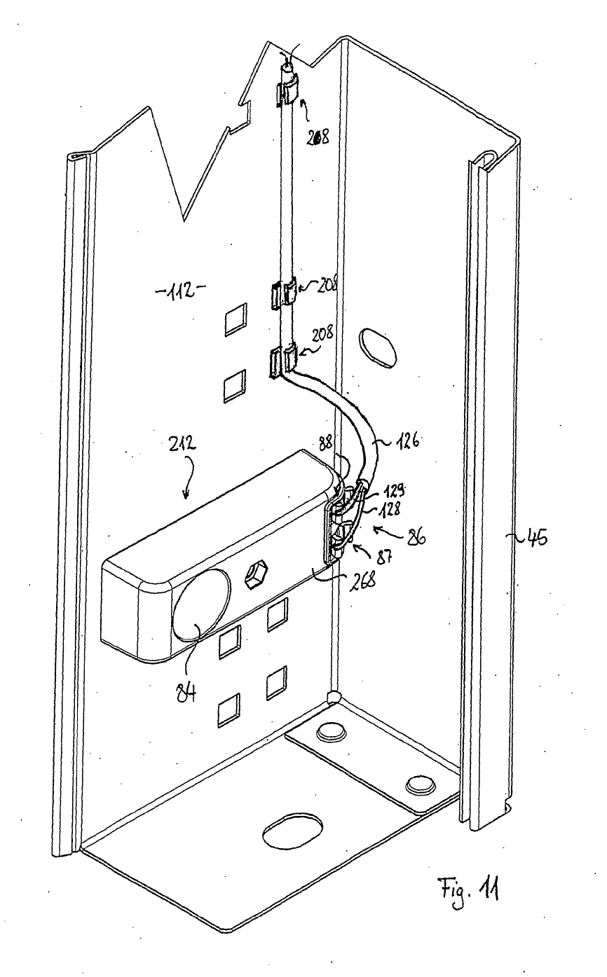

FIGS. 8 and 9 are each a view of two different embodiments of cable clips, by means of which connecting cables of the light barrier element can be simply routed;

FIG. 10 is an exploded view in perspective of a lower portion of a door frame of a sectional door and a light barrier element in a first embodiment with wiring elements to illustrate a further possibility of securing the light barrier optionally on the door frame or on the mounting fixture of the previous type;

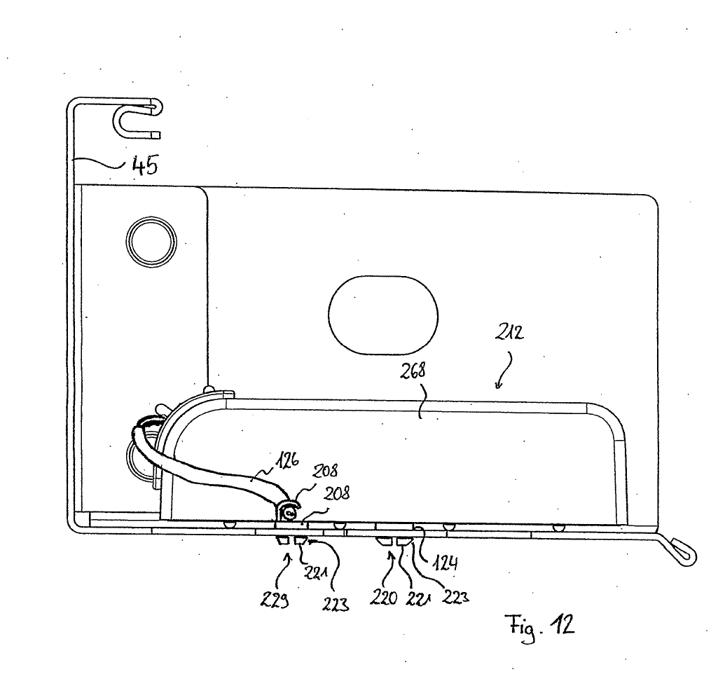

FIG. 11 is a view in perspective of the arrangement as shown in FIG. 10 from another direction in the assembled condition to illustrate how detenting is performed;

FIG. 12 is a top-down view of the arrangement as shown in FIGS. 10 and 11; and

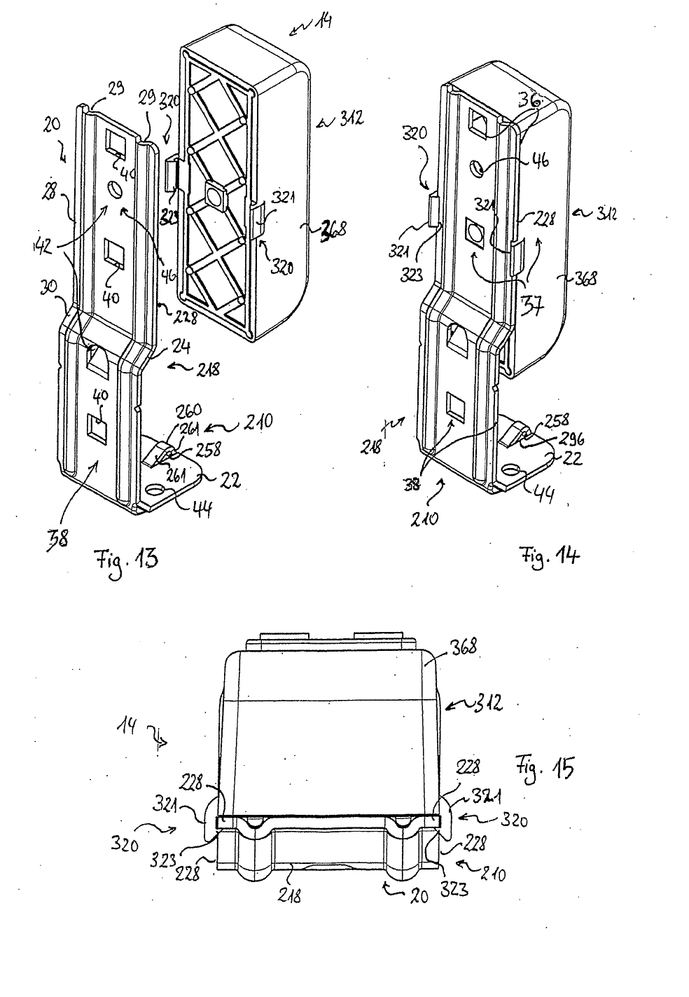

FIGS. 13 to 15 are differing views of a first embodiment of a light barrier element securable by means of a second embodiment of a mounting fixture.

Three embodiments of a light barrier element 12, 212, 312 of a light barrier 14 serving to monitor the action of a door powered by an operator will now be detailled with reference to the attached FIGS.

The light barrier element 12, 212, 312 is located in a light barrier housing 68, 268, 368 which in a front view is rectangular in shape. In a central portion there is provided in a first and third embodiment of the light barrier housing 68, 368 a thru-hole 74 communicating the front side 70 to the rear side 72 for a hexagon bolt 76 (see for example FIGS. 5 to 7).

The thru-hole 74 can serve to mount the light barrier housing 68, 368 by means of a mounting fixture 10, 210 configured as a mounting bracket 18, 218 with two legs 20 and 22 as shown in FIGS. 5 to 7 and 13 to 15. In addition to mounting the light barrier housing 68 as shown by means of the mounting fixture 10, 210 it is also possible because of the thru-hole 74 to mount the light barrier housing 68 for example directly on a wall.

In the second and third embodiment of the light barrier housing 268, 368 a detent means 220, 320 is provided for mounting on the mounting bracket 218 or on a door member, in this case a door frame 45 of a sectional door as is detailled further below.

Referring now to FIGS. 1-4 there is illustrated how the thru-hole 74 merges at the front side 70 into a recess 78 for the purpose of receiving the head of the hexagon bolt 76 locked non-rotatably.

At the rear side 72 the thru-hole 74 ports into a square protuberance 80 protruding from the rear side 72 configured for exact location in one of a plurality of selectable square notches 40 in the mounting fixture 10.

Provided furthermore at the rear side 72 is a total of eight hemispherical protuberances 82 which engage in matching reinforcement beads 29 provided there when the light barrier housing 68 is oriented parallel to the first leg 20. In this arrangement the protuberances 82 are distributed and arranged such that the protuberances 82 arranged in the vicinity of the protuberance 80 engage the reinforcement beads 29 also when the light barrier housing 68 is oriented transversely to the first leg 20.

Because of the protuberance/recess combination between the protuberances 80, 82 and the notches or beads 40, 29 the light barrier housing 68, 268, 368 can be located on the mounting bracket 18, 218 in one of a total of four (and not more) optional orientations.

For cost-effective production the light barrier housing 68, 268, 368 is preferably made of a tough high-strength plastics material.

Provided in the light barrier housing 68, 268, 368 to form the light barrier element 12, 212, 312 in each case is a photoelectric unit of the light barrier 14 which can be a transmitter or a receiver. To form the light barrier 14 a light barrier housing 68, 268, 368 provided with a transmitter needs to be secured to the one side of the door by means of the mounting fixture 10, 210 and a light barrier housing 68, 268, 368 provided with a receiver needs to be secured to the other side of the doorway by means of the mounting fixture 10, 210.

It is furthermore possible to provide in the light barrier housing 68, 268, 368 a transceiver with simply a reflector being located at the other end of the doorway.

Provided preferably in the light barrier housing 68, 268, 368 as a photoelectric unit for converting the light beam into a detectable signal and conversely is a photodiode 84 with its assigned electronic circuitry (not shown) serving as a transmitter or as a receiver depending on how it is activated and circuited. The light beam 32 to be transmitted and received respectively by the photodiode 84 can be ported through a portion 30 provided at the front side 70 transparent to the radiation employed.

In the example as shown, the light barrier element 12, 212, 312 is engineered as a two-wire system as is known in principle. For more details as regards the inner structure of the light barrier element 12, 212, 312 and how the light barrier 14 works as regards the two-wire connection and its circuiting with the door operator (not shown) reference is expressly made to German patent DE 20 2004 005 113 U1 making special mention that and how the light barrier element 12, 212, 312 can be operated with two cables as either an transmitter or as a receiver structured roughly the same depending on how activated and circuited.

To simplify connecting the two cables a connector in the form of a cable connector 86 with two clip-on terminals 87, 88 is provided in a lower portion near to the bottom edge of the front side 70 as are popular with home stereo speaker connectors.

The two clip-on terminals 87, 88 thus feature a contact element or clip element 89 biased in the clipped position by spring tension and featuring a finger scallop 90 for finger tip actuation from its clipped position by opening the central portion into which the stripped end of the cable can be inserted and which on removal of finger pressure results in the spring bias of the clip element 89 as produced by some kind of elastically element such as a compression or tension spring, torsional spring, spring clip, rubber element, etc. clamps the stripped edge of the cable in contact. Such clip-on terminals are popular in the electronics marketplace as speaker terminals, they thus requiring no more detailled description.

FIGS. 5, 6 and 7 show differing positions for mounting the light barrier element 12 in accordance with the first embodiment on the floor or door frame.

Referring now to FIG. 5 there is illustrated a first mounting position in which the light barrier housing 68 is secured lengthwise to the first leg 20 at a middle square notch 40 for the purpose of floor mounting. In this arrangement the light barrier housing 68 ends flush with the first leg 20 at the top, it being simply secured by the hexagon bolt 76 inserted in the thru-hole 74 and locked in place at the rear by a nut (not shown).

Provided, for example, for floor or wall mounting are two bolt/dowel combinations 94 by means of which the mounting bracket 18 can be securely fastened by engaging two holes drilled correspondingly in the floor by a floor or wall fastening means 44 provided at the second leg 22.

Orienting the light beam 32 transmitted or received by the photodiode 84 is possible because of a curved slot 64 by turning the mounting bracket 18, 218 about a bolting hole 63 with the bolt/dowel combinations 94 inserted.

Referring now to FIG. 6 there is illustrated a second mounting position which is comparable to the first mounting position as shown in FIG. 5, except that the light barrier housing 68 is secured to a further square notch 40 in the first leg 20 provided at the free end in thus being positioned higher than in the first mounting position.

Referring now to FIG. 7 there is illustrated a third mounting position in which again the light barrier housing 68 is secured to this square notch 40, but this time transversely to the projection of the first leg 20. In this way the mounting bracket 18, 218 can be secured to a vertical surface oriented roughly parallel to the dooway plane, for example to a wall or especially to a door frame.

To mount the light barrier housing 68 it is secured by means of the hexagon bolt 76 and the nut in the wanted mounting position in each case. Then referring now to FIGS. 8 and 9 all that is needed as indicated at 126 is to make the connections by the cable connector 86 with the aid of the clip-on terminals 87 and 88. The other end of the two-lead cable is connected to the door operator controller (not shown). The cable 126 can be neatly routed by means of self-adhesive clips 108 and 110 (see FIG. 8 or 9), an adequate number of these clips 108 or 110 being included in the accessory package of the light barrier 14.

Referring now to FIGS. 10 to 12 there is illustrated a second embodiment of a light barrier element 212 directly secured to a door frame 45 of a sectional door (not shown) by way of example. Like or correspondingly components have like reference numerals as in the first embodiment.

Except for the light barrier housing 268 the light barrier element 212 of the second embodiment corresponds to the light barrier element 12 of the first embodiment. The light barrier housing 268 of the second embodiment differs from the light barrier housing 68 of the first embodiment solely by a first detent means 220 at the rear side 72.

Instead of the thru-hole 74—and thus roughly in the middle of the rear side 71—the first detent means 220 features four detent tongues 221 each diametrally opposed to the other and provided at sides facing away from each other a detent nose 223. The detent tongues 221 are engineered elastically squeezable.

This enables the first detent means 220 to be clipped into place in a hole 124 drilled for securing the light barrier so that it can be positioned, for example, on the inside surface of a L-section wall 112. Positioning aids can be provided at the inside surface of the L-section wall 112 in one aspect (not shown) of this embodiment to position the light barrier housing 268 oriented as preselected. These positioning aids may be provided as stops or recesses for positively locating parts of the light barrier housing 268.

Referring now to FIGS. 10 to 12 there are illustrated alternative aspects of cable clips 208, each of which can be lip by integral second detent means 229 in square notches 130 in the door frame 45. These square notches 130 are provided regularly spaced along the door frame 45 in the L-section wall 112, defining a path within the L section of the door frame 45 for routing the cable 126 both safely, favorably and facilitated.

The square notches 40 in the mounting bracket 18 have in one preferred embodiment the same dimensions as the square notches 130 in the door frame 45 in thus enabling, when required, one of the cable clips 208 to also be clipped in place in one of the notches 40 in the mounting bracket 18 so as to route and locate the cable 126 in the immediate vicinity of the light barrier element 12. For instance, the cable 126 can be safely routed around and behind the mounting bracket 18 so that the cable 126 cannot flutter because of wind gusts and shock impact, for example, disrupting beaming.

Referring now to to FIGS. 10 to 12 there are illustrated also two leads 128 and 129 of the cable 126 and their connection to the clip-on terminals 87 and 88.

Machined in the mounting bracket 18 forming the mounting fixture 10 in accordance with a first embodiment is a bolting hole 46 for the bolt 76 dimensioned comparable to the hole 124 in the door frame 45. Thus, instead of directly securing the light barrier housing 268 as shown in FIGS. 10 to 12 in explaining the arrangement, in the second embodiment the light barrier element 212 can be clipped into place by means of the first detent means 220 in the mounting bracket 18 and then optionally secured in the region of any door by means of the mounting bracket 18.

Referring now to FIGS. 13 to 15 there is illustrated a second embodiment of a mounting fixture 210 with a modified mounting bracket 218 for securing a light barrier element 12, 212, 312 together with a light barrier element 312 in accordance with a third embodiment, like or corresponding components having like reference numerals as in the embodiment as discussed above to which reference is also made for more details.

The mounting bracket 218 in its second embodiment differs from the first mounting bracket 18 of the first embodiment merely by the configuration of the second leg 22. Provided at the second leg 22 is a strap 260 arranged in the region of the free end of the second leg 22. The strap 260 firstly features a longer middle portion 261 swept back at an angle to the side of the first leg 20 and its edge portion again swept back to the second leg 22 forming an angled end 262. In this arrangement the strap 260 is oriented within a cutout 296 machined in the free edge portion of the second leg 22 in thus protruding inwards only to the first leg 20. Now, when a stopper means is needed as a positioning aid for securing the mounting bracket 218 to a door member (not shown) the strap 260 simply needs to be depressed until the end 262 protrudes roughly at a right angle below the second leg 22 to thus form a stopper means 258 at the underside of the second leg 22 for stopping a recess or edge of a door member such as e.g. the frame of an up and over door (not shown).

The light barrier housing 368 in accordance with a third embodiment is configured the same as light barrier housing 68 in the first embodiment, except that a detent means 320 is now additionally configured at the rear side 72 for positioning at the long outer edges 228 of the mounting bracket 18, 218.

The third detent means 320 comprises in the middle of the longer side edges of the rear side 72 of the light barrier housing 368 a detent tongue 321. Each detent tongue 321 comprises at the side inswept to the light barrier housing 368 a detent nose 323 for clasping the edges 228 of the mounting bracket 218. For this purpose the detent tongues 320 can be elastically splayed.

In accordance with another embodiment (not shown) two of the square notches 40 in the mounting bracket 18, 218 are configured spaced so far from each other that the two detent tongues 320 can also engage the two square notches 40 to clasp the rims there. This enables the light barrier housing 368 to be optionally located either oriented with the mounting bracket 18, 218 as shown in FIGS. 13 to 15, or oriented perpendicular to the longitudinal extent of the mounting bracket 18, 218 as shown in FIG. 14, for instance, with the mounting bracket 18, 218. In this arrangement means are provided at mounting bracket 18, 218 and/or the light barrier housing 368 so that the protuberance 80 can be shaped to engage a correspondingly notch (not shown) in the mounting bracket 18, 218 also when oriented at a right angle.

In the example as shown, the light barrier 14 can be furnished as an identical accessory package for any type of door operator, for instance reversible, shafted or direct type operator, rotary, slider, slaved type operator, it being particularly an advantage that such an accessory is compatible with operators for different types of doors, for example, both sectional and up and over doors. Such an accessory comprises two intercompatible light barrier elements 12 or 212 or 312 for forming a light barrier 14 as well as two mounting fixtures 10, 210 and the various fasteners 76, 94, a length of two-wire cable 126 for connecting both light barrier elements 12, 212, 312 as well as a plurality of self-adhesive or clip-on cable clips 108, 110 or 208.

The cable 126 for routing by the clips 108, 110 or 208 enables the light barrier element 12 to be connected to an associated power supply, controller and/or analyzer, in other words to a door operator controller as described and shown in German patent DE 20 2004 005 113 U1 to which reference is made for further details as to the door operator and the door actuated thereby.

### LIST OF REFERENCE NUMERALS

10 mounting fixture
12 light barrier element
14 light barrier
18 mounting bracket
20 first leg
22 second leg
29 reinforcement beads
30 radiation-transparent portion
32 light beam
40 square notch
44 floor or wall fastening means
45 door frame (sectional door)
46 bolting hole
63 bolting hole
68 light barrier housing
70 front side
72 rear side
74 thru-hole
76 hexagon bolt
78 hexagon recess
80 square protuberance
82 humped protuberance
84 photodiode (photoelectric unit)
86 cable connector
87 first clip-on terminal
88 second clip-on terminal
94 bolt/dowel combination
108 self adhesive cable clip
110 self adhesive cable clip
126 two-lead cable
128 first lead
129 second lead
130 square notches on door frame
209 cable clip
210 mounting fixture (second embodiment)
212 light barrier element (second embodiment)
218 mounting bracket (second embodiment)
220 first detent means
221 detent tongue
223 detent nose
228 outer edges of mounting bracket
229 second detent means
258 stopper means
260 strap
261 middle portion
262 downswept end
296 cutout
268 light barrier housing (second embodiment)
312 light barrier element (third embodiment)
320 third detent means
321 detent nose
323 detent nose
368 light barrier housing (third embodiment)

1. A light barrier housing for a light barrier element configured as a transmitter and/or receiver module of a light barrier for monitoring a automated building closure, comprising:
a front side comprising a portion transparent to the radiation used by the light barrier for inputting and/or outputting of the light barrier beam serving monitoring, and a rear side facing the front side
characterized in that
provided at the light barrier housing is a cable connector for connecting the light barrier element to a controller or analyzer,
that the cable connector comprises at least one clip-on terminal arranged at the light barrier housing,
that the at least one clip-on terminal is provided with a clip element biased spring-loaded in a clipped position which is manually moveable without the need of a tool for insertion/removal of a stripped connecting cable end from the clipped position into a receiving position,
the clip element in the receiving position freeing a receiving opening for inserting the end of the cable, and
that configured at the clip element and/or a receiving portion contacted by the clip element in the clipped position with spring force is a contact surface electrically connected to the photoelectric unit, made of an electrically conductive material.

2. The light barrier housing as set forth in claim 1
characterized in that
the cable connector is configured as a two-wire connection with a first and second clip-on terminal.

3. The light barrier housing as set forth in claim 1,
characterized in that
at least one clip-on terminal is arranged at front side.

4. The light barrier housing as set forth in claim 1,
characterized in that
the at least one clip-on terminal is arranged at the an edge portion, particularly at an edge portion to be arranged at the bottom when in use as specified.

5. The light barrier housing as set forth in claim 1,
characterized in that
the at least one clip element is provided with a finger scallop for finger tip actuation of the clip element.

6. The light barrier housing as set forth in claim 1,
characterized in that
the outwardly visible portion of each of a plurality of clip elements is coded by a different marking particularly by a different color.

7. The light barrier housing as set forth in claim 1,
characterized in that
the light barrier housing comprises a thru-hole communicating the front side to the rear side for a fastener, particularly a bolt fastener.

8. The light barrier housing as set forth in claim 7,
characterized in that
at the front side the thru-hole ports into a recess suitable for positively engaging a bolt head.

9. The light barrier housing as set forth in claim 1,
characterized in that
configured at the rear side is a protuberance configuration and/or recess as a positioning aid for fitting the light barrier housing preoriented.

10. The light barrier housing as set forth in claim 1,
characterized in that
for securing the light barrier housing directly to an element of a door or mount a detent means is provided for clasping a hole or an edging at the door or mounting fixture.

11. The light barrier housing as set forth in claim 10,
characterized in that
the detent means is provided at the rear side.

12. The light barrier housing as set forth in claim 10,
characterized in that
the detent means comprises a plurality of detent tongues configured to engage a circular or rectangular notch at the door or mounting fixture, at sides facing away from each other with at least one detent nose and are elastically squeezable for detenting.

13. The light barrier housing as set forth in claim 12,
characterized in that
the detent means is arranged roughly in the middle of the rear side, the detent tongues being arranged spaced away from the rim edges of the rear side.

14. The light barrier housing as set forth in claim 10,
characterized in that
the detent means comprises a plurality of detent nose configured to clasp two substantially parallel edges facing away from each other at the door or at the mount, each featuring at least one detent nose at sides facing each other and which for detent means are elastically splayable.

15. The light barrier housing as set forth in claim 14,
characterized in that
the detent tongues are arranged in the vicinity of rim edges of the rear side.

16. A light barrier element configured as a transmitter and/or receiver module of a light barrier for monitoring an automated door, including a photoelectric unit for converting electromagnetic radiation into an electronically detectable signal and/or vice-versa,
characterized in that
the photoelectric unit is accommodated in a light barrier housing as set forth in any of the preceding claims and is connectable by means of the cable connector arranged at the light barrier housing to a power supply, controller and/or analyzer.

17. The light barrier element as set forth in claim 16,
characterized in that
it is configured as a two-wire system and that the cable connector is configured as a two-wire connector with two of the clip-on terminals.

18. A light barrier with two light barrier elements forming a light barrier link at least one of which is configured in accordance with claim 16.

19. The light barrier as set forth in claim 18, characterized by a preferably two-wire cable and by a plurality of clips either self-adhesive or each comprising at least one element of a detent means for routing the cable from the light barrier element to the power supply, controller and/or analyzer.

20. A door powered by a door operator, the action of which is monitored by a light barrier as set forth in claim 18.

21. A door operator for motorized door, particularly a garage, bay closure or driveway door, characterized by at least one light barrier housing as set forth in claim 1.

22. The door operator as set forth in claim 21, characterized by a light barrier including a light barrier element to detect an obstacle standing in the way of the door and to stop and/or reverse action of the door when an obstacle is detected.
